(19) United States
(12) Patent Application Publication
(10) Pub. No.: US 2025/0006810 A1
(43) Pub. Date: Jan. 2, 2025

(54) TRANSISTOR WITH CHANNEL-SYMMETRIC GATE

(71) Applicant: Intel Corporation, Santa Clara, CA (US)

(72) Inventors: Shao-Ming Koh, Tigard, OR (US); Manish Chandhok, Beaverton, OR (US); Marvin Paik, Portland, OR (US); Shahidul Haque, Portland, OR (US); Jason Klaus, Portland, OR (US); Asad Iqbal, Beaverton, OR (US); Patrick Morrow, Portland, OR (US); Nikhil Mehta, Portland, OR (US); Alison Davis, Portland, OR (US); Sean Pursel, Tigard, OR (US); Steven Shen, Hillsboro, OR (US); Christopher Rochester, Hillsboro, OR (US); Matthew Prince, Portland, OR (US)

(73) Assignee: Intel Corporation, Santa Clara, CA (US)

(21) Appl. No.: 18/216,514

(22) Filed: Jun. 29, 2023

(51) Int. Cl. H01L 29/423; H01L 21/28; H01L 21/3213; H01L 29/06; H01L 29/66; H01L 29/775

(52) U.S. Cl. CPC H01L 29/42392; H01L 21/28123; H01L 21/32136; H01L 21/32139; H01L 29/0673; H01L 29/66439; H01L 29/775

(57) ABSTRACT

Transistor structures with gate material self-aligned to underlying channel material. A channel mask material employed for patterning channel material is retained during selective formation of a second mask material upon exposed surfaces of gate material. The channel mask material is then thinned to expose a sidewall of adjacent gate material. The exposed gate material sidewall is laterally recessed to expand an opening beyond an edge of underlying channel material. A third mask material may be formed in the expanded opening to protect an underlying portion of gate material during a gate etch that forms a trench bifurcating the underlying portion of gate material from an adjacent portion of gate material. The underlying portion of gate material extends laterally beyond the channel material by an amount that is substantially symmetrical about a centerline of the channel material and this amount has a height well controlled relative to the channel material.

### BACKGROUND

For advanced integrated circuits, the performance of a transistor is dependent, in part, on parasitic capacitance. In dense transistor arrays, one source of parasitic capacitance stems from coupling between gate electrodes, or “gates” of adjacent transistors. The gate coupling capacitance is a function of spacing between adjacent gates and can be reduced by increasing the spacing.

Spacing between the gates of adjacent transistors is advantageously maximized for a given lateral transistor channel pitch. However, conventional manufacturing techniques define transistor channel pitch with a first lithographic mask and define gate spacing with a second lithographic mask. Accordingly, transistor channel pitch and/or gate coupling capacitance must accommodate non-zero misregistration between these two masks.

Transistor architectures that could reduce or eliminate the misregistration between gates and transistor channels would therefore be commercially advantageous for reducing parasitic capacitance and/or transistor pitch of a given CMOS integrated circuit (IC).

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods for forming a transistor structure having a channel-symmetric gate material that is self-aligned to transistor channel material, in accordance with some further embodiments

FIGS. 2, 3, 4, 5, 6, 7, 8, 9, 10, 11, and 12A are isometric views of transistor structures evolving as the methods illustrated in FIG. 1 are practiced, in accordance with some embodiments;

FIGS. 12B and 12C are cross-sectional views through a gate of the transistor structures shown in FIG. 12A, in accordance with some embodiments;

FIG. 12D is a cross-sectional view through a source or drain of the transistor structures shown in FIG. 12A, in accordance with some embodiments;

FIG. 13A is an isometric view of the transistor structure shown in FIG. 12A evolving as the methods illustrated in FIG. 1 are practiced, in accordance with some embodiments;

FIG. 13B is a cross-sectional view through a gate of the transistor structures shown in FIG. 13A, in accordance with some embodiments;

FIG. 14 illustrates a mobile computing platform and a data server machine employing an IC device with transistor structures that include a channel-symmetric gate, in accordance with some embodiments; and

FIG. 15 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

In accordance with embodiments herein, integrated circuitry includes a transistor structure comprising a gate electrode, or “gate,” that is self-aligned to underlying channel material.

A channel mask material employed for patterning channel material is surrounded with gate material that has a substantially co-planar top surface. The channel mask material is retained during a selective formation of a second mask material upon exposed surfaces of gate material. With a top surface of the gate material then protected by the second mask material, the channel mask material is thinned to expose a sidewall of adjacent gate material. The exposed gate material sidewall is laterally recessed to expand an opening beyond an edge of underlying channel material. A third mask material may be formed in the expanded opening to protect an underlying portion of gate material during a gate etch that forms a trench bifurcating the underlying portion from an adjacent portion of gate material. With the third mask material occupying space self-aligned to the channel mask material, the underlying portion of gate material will extend laterally beyond the channel material by an amount that is substantially symmetrical about a centerline of the channel material and has a height well controlled relative to the channel material.

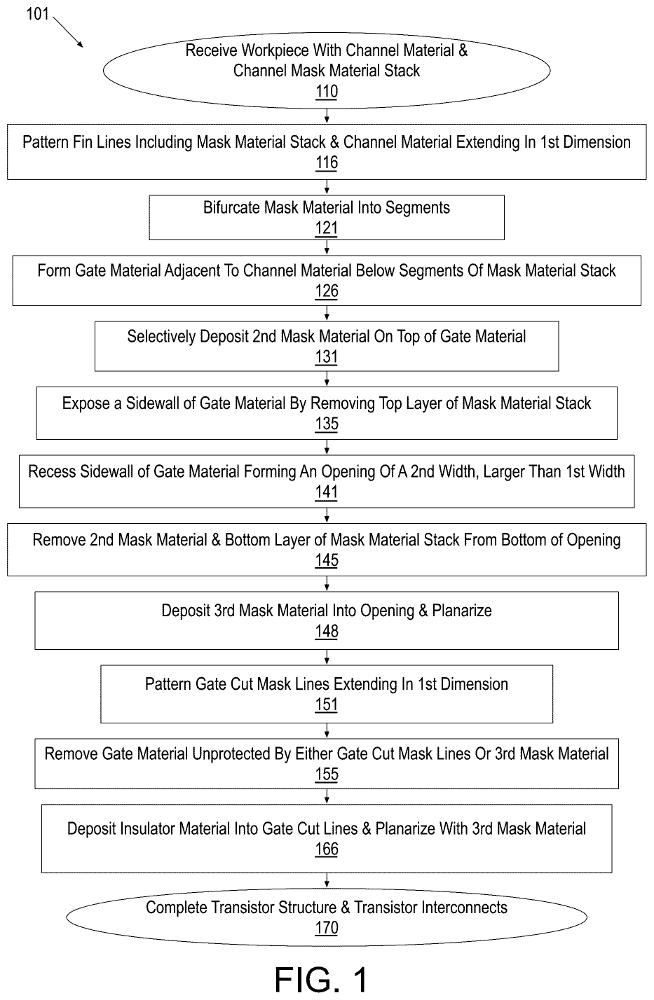

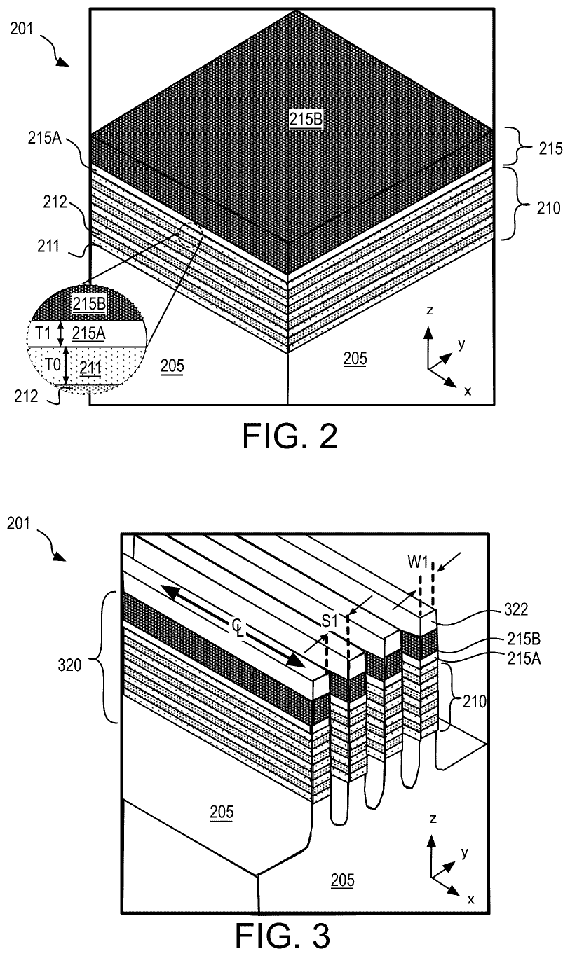

FIG. 1 is a flow diagram illustrating methods 101 for fabricating a transistor structure having channel-symmetric gate material that is self-aligned to channel material, in accordance with some embodiments. FIG. 2-12A are isometric views of transistor structures evolving as the methods 101 are practiced, in accordance with some embodiments. The depicted transistor structures further highlight structural features associated with an exemplary practice of methods 101. However, the practice of methods 101 need not result in all the structures exactly as illustrated in FIG. 2-12A.

Referring first to FIG. 1, methods 101 begin at input 110 with receipt of a workpiece including transistor channel material. In some examples, the workpiece received at input 110 comprise a 300-450 mm diameter wafer. The workpiece may include a substantially monocrystalline material, for example, and further include any number of channel material layers over the monocrystalline material. The workpiece includes channel mask material over the channel material layer(s). In advantageous embodiments, the mask material comprises a stack of two or more mask material layers, each layer having a composition distinct from the other. Thicknesses of the mask material layers may vary with implementation, but in some embodiments a bottom mask material layer is significantly thinner than a top mask material.

In the example illustrated in FIG. 2, a workpiece portion 201 comprises a mask material stack 215 over a transistor channel material stack 210. Channel material stack 210 further includes a plurality of bi-layers. Each bilayer comprising a sacrificial material 211 and a channel material 212. The number of bi-layers may vary with implementation. Channel material 212 may have any composition suitable for a channel of a field effect transistor (FET). In some examples, channel material 212 is substantially silicon. In other embodiments, channel material 212 comprises germanium (e.g., Si₁₋ₓGe_{X}, Ge₁₋ₓSN_{X}, or substantially pure Ge). In some embodiments, channel material 212 includes a transition metal and a chalcogen. The transition metal may be any transition metal such as any element of groups 4 through 11, the group 3 elements scandium and yttrium, and the inner transition metals (e.g., f-block lanthanide and actinide series). Notable transition metals are molybdenum and tungsten. The chalcogen may be sulfur, selenium, and tellurium. In still other embodiments, channel material 212 comprises one or more metals and oxygen (i.e., metal oxide semiconductor), such as, but not limited to, Indium, gallium zinc oxide (IGZO).

Channel material 212 is advantageously crystalline. Although the crystalline semiconductor includes polycrystalline thin film material, channel material 212 may be substantially monocrystalline. In some embodiments where channel material 212 is substantially pure silicon, the crystallinity of channel material 212 is cubic with a top surface having crystallographic orientation of (100), (111), or (110), for example. Other crystallographic orientations are also possible. Channel material 212 may also be polycrystalline or amorphous, for example in certain metal chalcogen and/or metal oxide embodiments.

Sacrificial material 211 has a different composition than channel material 212. In some examples, sacrificial material 211 has more germanium than channel material 212. For example, where channel material 212 is predominantly silicon, sacrificial material 211 is Si₁₋ₓGe_{X}, and X may be advantageously between 0.3-0.35. In other embodiments, sacrificial material 211 has less germanium than channel material 212. For example, where the channel material 212 is Si₁₋ₓGe_{X}, sacrificial material 211 may be predominantly silicon. In other embodiments where channel material 212 is a first metal chalcogenide, sacrificial material 211 may be a second metal chalcogenide or a metal oxide, for example.

Sacrificial material 211 is also advantageously crystalline. Although the crystalline semiconductor includes polycrystalline thin film material, sacrificial material 211 may be substantially monocrystalline. In some embodiments where the crystallinity of channel material 212 is cubic with a top surface having crystallographic orientation of (100), (111), or (110), for example, sacrificial material 211 has this same crystallinity. Sacrificial material 211 may also be polycrystalline or amorphous, for example in certain metal chalcogen and/or metal oxide embodiments.

Mask material stack 215 may include any number of layers with each material layer having any composition known to be suitable as a hardmask for patterning channel material stack 210. In some examples, mask material stack 215 includes at least a bottom mask material layer 215A and a top mask material layer 215B. In exemplary embodiments, bottom mask material layer 215A comprising silicon and at least one other majority constituent, such as oxygen (e.g., SiO), nitrogen (e.g., SiN) or carbon (e.g., SiC). Top mask material layer 215B may also comprise predominantly silicon and at least one other majority constituent (e.g., O, N, C). Although only two layers are illustrated in FIG. 2, mask material 215 may comprise any number of material layers having a total thickness that may vary with implementation, but in some examples is within the range of 20-60 nm.

As shown in the expanded view of FIG. 2, bottom mask material layer 215A is in direct contact with sacrificial material 211. Sacrificial material 211 has a thickness TO, which may be well controlled through an epitaxial growth process, for example to within <1 nm of a target thickness such as 5-10 nm. Bottom mask material layer 215A has a thickness T1, which again may be well controlled through a deposition process, for example to within <1 nm of a target thickness. In exemplary embodiments, bottom mask material layer thickness T1 is less than 10 nm, and may be 5 nm, or less. In the example illustrated, bottom mask material layer thickness T1 is less than sacrificial material layer thickness TO.

Returning to FIG. 1, at block 116 channel material is made non-planar (e.g., into a “fin”) according to a first lithographic patterning process. The channel mask material over the channel material is patterned to have a lateral width in a first dimension. Underlying channel material is further patterned according to the channel mask material pattern. For exemplary embodiments, fin lines may extend any length along a first dimension and have a width in a second, orthogonal dimension. Any lithographic masking process and material etch process(es) may be practiced at block 116.

In the example illustrated in FIG. 3, fin lines 320 have been patterned into workpiece portion 201. A lithographic mask 322 defines fin lines 320 with a first lateral width W1 coincident with the y-axis (i.e., orthogonal to the direction of the longitudinal centerline). Laterally adjacent fin lines 320 are separated by a space S1. Line width W1 and space S1 define an y-dimensional pitch of lines 320. Each fin line 320 comprises channel material stack 210, bottom mask material layer 215A and top mask material layer 215B. Each fin line 320 may also comprise a sub-fin portion of underlying substrate material 205. Fin lines 320 are substantially parallel and extend laterally a longitudinal length in the x-dimension. An arrow demarks a centerline (C_{L}) of one fin line 320 that is coincident with an x-axis.

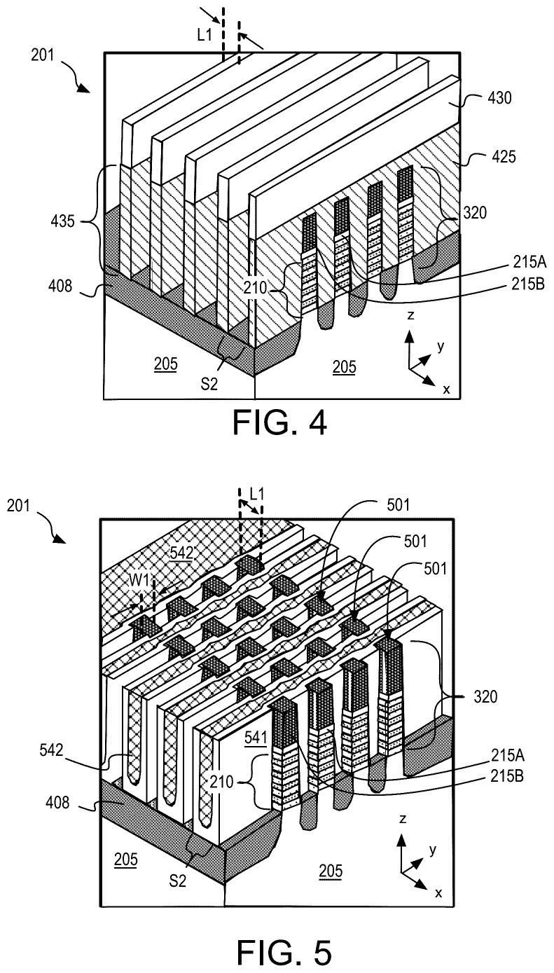

Returning to FIG. 1, methods 101 continue at block 121 where the line mask material is bifurcated into segments with each segment located over a transistor channel region. This bifurcation may be with a second lithographic patterning process defining lines that are substantially orthogonal to the fin lines. In the example shown in FIG. 4, workpiece portion 201 now includes an isolation material 408 between fin lines 320. Any suitable sacrificial gate material 425 is deposited over the fin lines 320 and patterned into gate mandrel lines 435, for example according to a photolithographically patterned mask 430. As shown, gate mandrel lines 435 are substantially parallel and extend laterally over a longitudinal length coincident with the y-axis.

Each gate mandrel line 435 has a transverse length L1 that is over an underlying segment of mask material layers 215A, 215B, and an underlying length of channel material stack 210. A space S2 is between adjacent gate mandrel lines 435. With each gate mandrel line 435 protecting underlying channel material, source or drain material (not depicted) may be formed within each space S2 to couple with opposite ends of each transistor channel region. Any technique(s) may be practiced to form source and drain regions, for example comprising a high concentration of impurities that impart either p-type or n-type conductivity.

As further illustrated in FIG. 5, spaces S2 have been backfilled with a gate spacer comprising one or more spacer insulator materials 541 and 542. Spacer insulator materials 541, 542 may be deposited by any process and then planarized with a top surface of top mask material layer 215B and/or a top surface of gate mandrel material (not depicted). Although a gate spacer insulator may have any composition, in exemplary embodiments spacer insulator materials 541 and 542 are both dielectrics. Advantageously, spacer material 541 and/or 542 has a different chemical composition than that of top mask material layer 215B. Spacer insulator material 541 and/or 542 may also have a different composition than the gate mandrel lines so that the gate mandrel lines may be removed selectively to spacer insulator material 541 and/or 542. As illustrated in FIG. 5, removal of the gate mandrel lines exposes segments 501 of top mask material layer 215B. Each segment 501 has the length L1 and the width W1. Within each segment 501 there a segment of channel material stack 210.

Methods 101 (FIG. 1) continue at block 126 where gate material is formed adjacent to the channel material. Any suitable gate material(s) may be formed over one or more surfaces of the channel material. In advantageous embodiments, gate material is formed at least adjacent to a sidewall of channel material. Gate material may be formed over any gate insulator suitable for the channel material composition. Gate material may also have any composition suitable for the channel material composition, for example to achieve a desired transistor threshold voltage, etc.

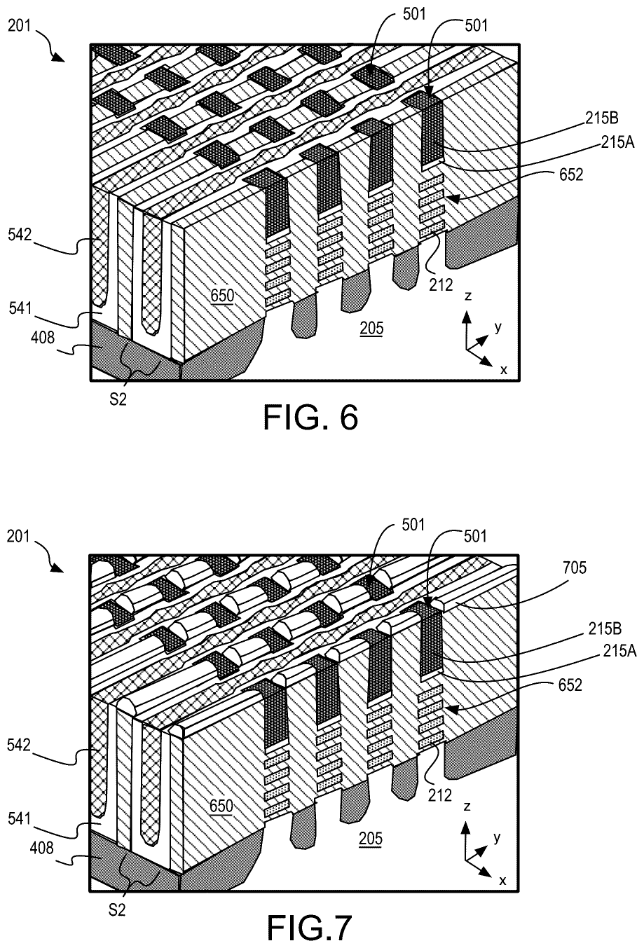

In the example illustrated in FIG. 6, gate material 650 is occupying a region between adjacent spacer insulator material 541. As shown, gate material 650 backfills regions within segments 501 where sacrificial material has been removed from between layers of channel material 212. Any gate insulator material 652, such as a high-k (e.g., >9) dielectric including oxygen and silicon or one or more metals, may be between channel material 212 and gate material 650. Gate material 650 may be deposited to be essentially where the gate mandrel material was previously removed. Gate material 650 may have any composition, for example comprising platinum, nickel, molybdenum, tungsten, titanium, nitrides such as titanium nitride, or tungsten silicon nitride, etc. In some embodiments, gate material 650 includes a work function metal and a fill metal. Gate material 650 may be deposited and planarized with a surface of top mask material layer 215B and/or spacer materials 541, 542.

Returning to FIG. 1, methods 101 continue at block 131 where a mask material is selectively formed on exposed surfaces of the gate material. In exemplary embodiments, a selective deposition process is practiced at block 131 to deposit mask material on a surface of the gate material at a much higher rate than on a surface of surrounding materials. For exemplary embodiments, where gate material is a metal and surrounding materials are insulators (e.g., dielectric materials) the resulting heterogenous surface may be leveraged to deposit a material, primarily on the gate material. The deposition of mask material at block 131 is therefore self-aligned to the gate material and/or to the surrounding insulator materials.

In the example illustrated in FIG. 7, mask material 705 has been selectively deposited upon surfaces of gate material 650. The composition of mask material 705 may vary with implementation. In some exemplary embodiments where gate material 650 is metallic and spacer insulator materials 541, 542 are dielectric materials, mask material 705 is silicon (e.g., amorphous silicon). An α-silicon mask material 705 is advantageously of a significantly different composition than both top channel mask material layer 215B and spacer insulator materials 541, 542.

Methods 101 (FIG. 1) continue at block 135 where the channel mask material stack is thinned, for example by removing the top mask material layer selectively to the bottom mask material layer. A sidewall of adjacent gate material is exposed where the channel mask material is removed. Any etch process selective to the top channel mask material may be practiced at block 135.

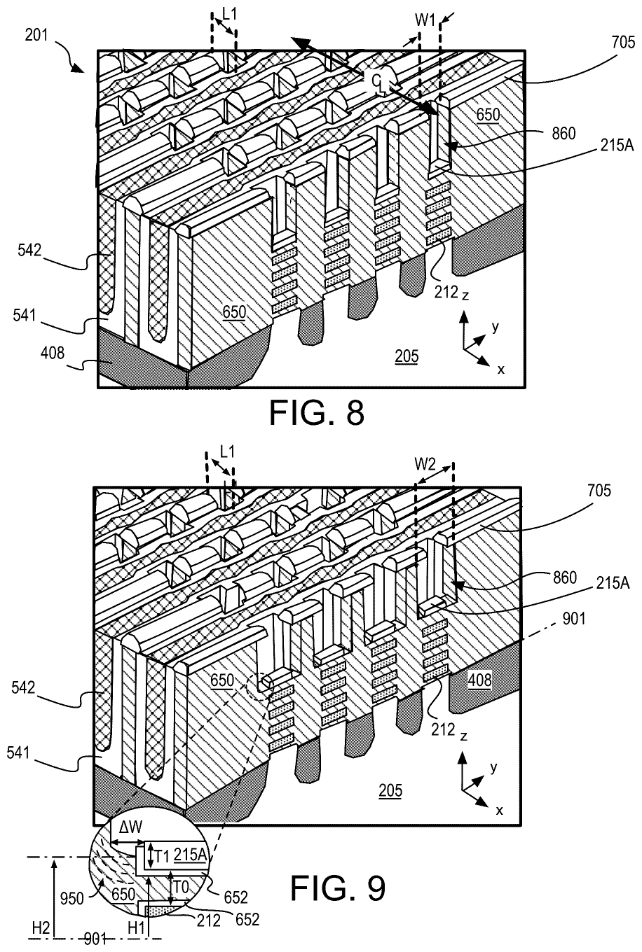

In the example illustrated in FIG. 8, top channel mask material layer 215B has been removed to form a cavity or opening 860. Bottom channel mask material layer 215A remains at the bottom of opening 860 protecting an underlying portion of gate material 650. Although implementations may vary, in one example where mask material 705 is α-silicon and spacer insulators 541, 542 are SiO, a top channel mask material layer 215B of SiN may be selectively removed and stopped on a bottom channel mask material layer 215A of SiC. A SiN etch is also selective to gate material 650. Because the initial lateral width W1 of mask material segments 501 defined the channel material width as a function of the fin line patterning process, opening 860 is self-aligned to mask material and retains lateral width W1. A plurality of openings 860 are co-linear along a centerline (C_{L}) demarked by an arrow, which in the illustrated example is coincident with the x-axis. Each opening 860 is symmetrical about the depicted centerline (C_{L}) of channel material 212.

Returning to FIG. 1, methods 101 continue at block 141 where an exposed sidewall of gate material is laterally recessed, for example with a well-controlled etch process, such as atomic layer etch (ALE). The recess etch of gate material expands the opening or cavity within the gate material to a second lateral width, larger than the initial lateral width of the channel mask material stack. Parameters of the recess etch process may be selected according to the composition of the gate material as embodiments are not limited in this context.

In the example illustrated in FIG. 9, a recess etch of gate material 650 has expanded opening 860 to a lateral width W2. For exemplary recess etch implementations, spacer insulator material 541 is not similarly recessed so that the lateral length of opening 860 remains substantially length L1. Lateral width W2 is larger than lateral width W1 by twice amount ΔW, further illustrated in the expand view showing a lateral amount of gate material 650 adjacent to an end of bottom channel mask material 215A. The etch may be isotropic or with an angled (sloped) directional ion etch that can be controlled to recess a sidewall of gate material 650 by equal amounts on opposite sides of a centerline length L1 through opening 860 to reach a desired expanded lateral width W2. Lateral width W2 can remain centered about a centerline of opening 860 aligned with the x-dimension. Opening 860 therefore remains self-aligned to the underlying channel material 212.

Depending on characteristics of the gate material sidewall recess etch, a lateral amount of gate material 650 may be recessed below a top surface of bottom channel mask material 215A to a height H2 relative to a reference plane 901. In this example, reference plane 901 is an x-y plane that is at an interface of gate material 650 and isolation material 408. However, the reference plane may be any x-y plane substantially parallel to a plane of the workpiece defining it's working area. As illustrated by dashed lines 950, height H2 may vary with the extent of gate material sidewall recess and therefore may be very well-controlled (e.g., by ALE) relative to a height H1 of gate material 650 underlying bottom channel mask material 251A. In the exemplary embodiment, height H2 is greater than height H1, but notably will not be greater than height H1 summed with the bottom channel mask material thickness T1. Hence, height H2 is advantageously no more than 10 nm (e.g., ˜5 nm) greater than height H1. Height H2 may be less than height H1, but advantageously by no more than 10 nm, ensuring the recess etch of gate material 650 does not expose gate insulator 652 surrounding underlying channel material 212. As ALE can be controlled to <1 nm precision, amount ΔW and bottom channel mask material thickness T1 may be selected to ensure height H2 is advantageously within 5 nm of height H1 and more advantageously no greater than height H1. The small magnitude of gate material recess can be contrasted with depth of opening 860, which as a function of the top mask material layer thickness, is advantageously many times the difference in height H2 and height H1.

Returning to FIG. 1, methods 101 continue at block 145 where mask materials are removed from both the bottom of the opening or cavity within the gate material, as well as from over a top surface of the gate material. The etch process(es) performed at block 145 may remove one or more of residual gate insulator material, residual spacer material, residual isolation material, or any other residual thin film material that may have collected as a lining on a sidewall of the channel mask material stack prior to deposition of the gate material. Another mask material of any suitable composition may then be deposited within the opening cavity and planarized with the top surface of the gate material at block 148. Operations performed at blocks 145 and 148 may be combined or performed in any order as embodiment are not limited in this context.

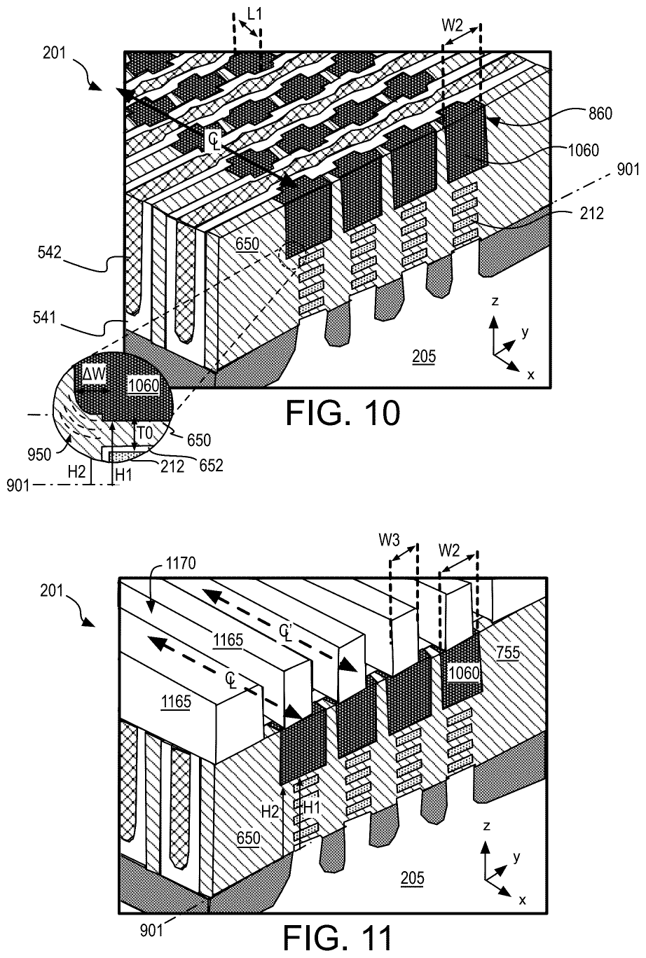

In the example shown in FIG. 10, a mask material 1060 substantially backfills opening 860 and has a top surface substantially co-planar with top surfaces of gate material 650 and spacer insulators 541, 542. As shown mask material 1060 has the enlarged lateral width W2 and therefore may function as a protective cap self-aligned to channel material 213 so that an amount ΔW by which a gate material 650 extends laterally beyond a sidewall of channel material 212 is ensured to be symmetrical about the centerline of channel material 212. Accordingly, gate material 650 surrounding channel material 212 may be more precisely controlled to have a minimal amount of overlap without risk of inadvertently exposing one side of the channel material 212, for example because of misalignment between multiple lithographic patterning processes.

Mask material 1060 advantageously has a chemical composition distinct from gate material 650 and spacer insulators 541, 542, enabling all of these materials to be subsequently etched by one or more processes which mask material 1060 can survive. As one example, mask material 1060 may have a composition similar to that of one of the channel mask material layers (e.g., SiN). However, other materials (e.g., amorphous carbon (α-carbon) are also possible.

As further illustrated in the expanded view of FIG. 10, mask material 1060 protects a portion of gate material 650 that is directly over channel material 212 (e.g., having height H1) as well as adjacent portions corresponding to amount ΔH beyond a sidewall of channel material 212 (e.g., having height H2). As shown, each cap of mask material 1060 is aligned along the original fin centerline demarked by an arrow coincident with the x-axis. Each cap of mask material 1060 has a length of approximately L1 and has the width W2, which is symmetrical and/or centered about the fin centerline (C_{L}).

With gate material protected by a cap of mask material having a self-aligned expanded width, the cap may be employed as an etch mask during a patterning process that defines a width of the gate material at block 151 (FIG. 1). This “gate-cut” patterning process may, for example, pattern lines substantially parallel to the fin lines patterned at block 116. The patterning process at block 151 may entail any lithographic technique(s) and can be expected to have some non-zero misregistration relative to the patterning process performed at block 116.

FIG. 11 illustrates workpiece portion 201 after patterning mask lines 1165. As shown, mask lines 1165 have a centerline (C_{L}′), which may be approximately aligned with fin line centerline (C_{L}), but have some non-zero misregistration (C_{L}-C_{L}′). In this example, each mask line 1165 overlapping mask material 1060 has a width W3 that is sufficiently smaller than width W2 to ensure edges of mask material 1060 extend beyond edges of mask line 1165 so that a misregistration of mask lines 1165 does not impact the patterning of gate material 650 proximal to channel material 212.

Returning to FIG. 1, methods 101 continue at block 155 where gate material not protected by either the mask material formed at block 148 or the mask material formed at block 151 is removed. The gate-cut pattern generated at block 155 is a summation of the polygons of mask material formed at block 148 and polygons defined lithographically at block 151. The mask pattern defined at block 151 may therefore overlap the mask material deposited at block 146, or not. Any etch process capable of removing gate material of a particular composition may be practiced at block 155.

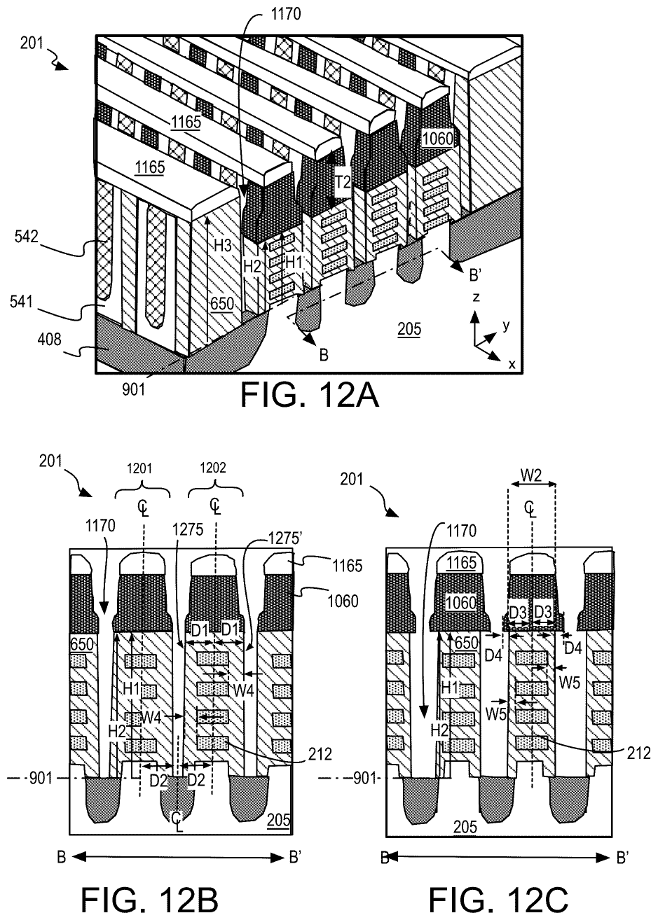

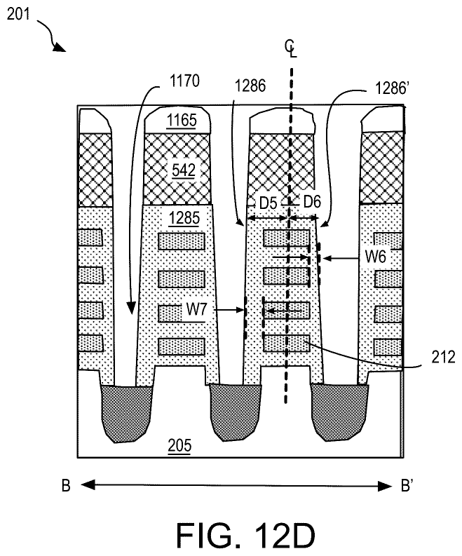

As further illustrated in FIG. 12A, gate cut trenches 1170 have been etched into workpiece portion 201. As shown, trenches 1170 are located within spaces between adjacent mask lines 1165 and are further limited by the presence of mask material 1060. Trenches 1170 extend through gate material 650, exposing isolation material 408, and may extend into and/or through isolation material 408 (e.g., into substrate material 205). In this example, trenches 1170 also extend through spacer insulator materials 541, 542. The depicted shouldering or necking of mask material 1060 is indicative of incomplete consumption of the thickness of mask material 1060 during the gate cut/trench etch process, which ensures all gate material under mask material 1060 is protected from the etch process. Hence, mask material thickness T2 may be selected to ensure mask material 1060 survives the gate cut etch process(es). The thickness T2 may then be used to determine minimum thicknesses of the preceding mask materials from which mask material 1060 is derived.

Notably, according to methods 101 (FIG. 1), gate material adjacent to transistor structures can retain a much greater height (thickness) than is retained within transistor structures. For example, as shown in FIG. 12A, gate material 650 protected by only a mask line 1165 (with no intervening mask material 1060) has a height H3 from reference plane 901, which is much larger than heights H1, H2. This significantly greater height H3 is indicative of a non-gate-etch back process, whereby gate material 650 separated from transistor structures need not be thinned through an etchback process. As the vertical height of a gate etchback process is more difficult to control than the gate material etch process(es) described in methods 101, the greater height H3 is also indicative of better control over heights H1, H2.

As shown in FIG. 12A, a top surface of gate material 650 having height H3 is substantially coplanar with a top surface of a spacer insulator material 541. A top surface of gate material 650 having height H3 is also substantially coplanar with a top surface of mask material 1060. Gate material 650 of height H3 may be integrated into circuitry in any capacity to have any functionality. In some embodiments, gate material 650 of height H3 is merely dummy structure filler adjacent to transistor structures. In other embodiments, electrical routing (e.g., a trace or resistor) within an integrated circuit comprises gate material 650 of height H3. For such routing features, the difference in vertical heights (H3 vs. H1/H2) may be leveraged during subsequent formation of contacts (not depicted) to these different (e.g., transistor vs. non-transistor) portions of gate metal.

FIG. 12B is a cross-sectional view along the B-B′ line illustrated in FIG. 12A. As shown in FIG. 12B, two adjacent transistor structures 1201 and 1202 are laterally separated by one trench 1170. Gate material 650 is centered about the centerline (C_{L}) of channel material 212 for each transistor structure 1201, 1202. Accordingly, gate material 650 has sidewalls 1275 and 1275′ on opposite sides of the channel centerline that are spaced the same distance D1 from the channel centerline. A lateral gate overlap width W4 beyond an adjacent sidewall of channel material is therefore equal on both sides of the channel centerline within the y-z plane illustrated in FIG. 12A. Likewise, a centerline (CL) of trench 1170 is precisely spaced by distance D2 symmetrically between two adjacent transistor structures 1201, 1202. Accordingly, gate material end-to end spacing is equal to approximately twice distance D2, which is fin pitch in the y-dimension, minus twice distance D1.

As further illustrated in FIG. 12B, lateral gate overlap width W4 has a height H2 that is well controlled relative to height H1 at the channel centerline. Hence, not only is the lateral width of gate material 650 precisely controlled, the top surface of gate material 650 is precisely controlled to be nearly planar (e.g., height H2 within 5 nm height H1).

With gate material overlap width W4 substantially symmetrical, gate material sidewalls 1275 and 1275′ may be laterally recessed, in accordance with some further embodiments. For example, as further illustrated in FIG. 12B, an etch process may be practiced after the gate cut patterning to reduce the gate overlap width to W5. Any isotropic or directional ion etch process may be practiced to trim the lateral width (e.g., y-dimension) of gate material 650 to be something smaller than width W2 of mask material 1060. The etch process may be similar to, or substantially same as, the sidewall recess etch preformed at block 141 of methods 101 (FIG. 1), for example. Following such an etch, gate material sidewalls 1275 and 1275′ are spaced the same distance D3 from the channel centerline and mask material 1060 overhangs gate material sidewalls 1275 and 1275′ by a lateral distance D4 indicative of the gate material recess etch. Accordingly, gate material end-to end spacing becomes equal to approximately twice distance D2 minus twice distance D3, which has been reduced from distance D1 by the distance D4.

The self-aligned gate material illustrated in FIG. 12A-12C can be contrasted with transistor source and drain material, which may not be similarly self-aligned. For example, FIG. 12D illustrates a cross-sectional view again along the B-B′ plane, but passing through source (drain) material 1285. As shown, spacer material 542 is over source (drain) material 1285. Trench 1170 pass through both spacer material 542 and source (drain) material 1285. Source (drain) material 1285 is therefore not self-aligned to a centerline (C_{L}) of channel material 212. In the illustrated example, one source (drain) material sidewall 1286 is a distance D5 from the channel material centerline while an opposing sidewall 1286′ on the opposite side of the channel material centerline (within y-z plane) is a different distance D6 from the channel material centerline. In view of the difference in centering about the channel material centerline, overlap of source (drain) material is of differing widths W5 and W6. This difference may be a result of misalignment in the gate-cut mask, for example, and therefore the source (drain) cross-section in FIG. 12D serves as a useful reference to the gate cross-sections of FIG. 12A-12C. In exemplary embodiments, gate material is more symmetrical about a centerline of the channel material than source (drain) material.

Returning to FIG. 1, methods 101 continue at block 166 where the trenches formed at block 155 may be at least partially backfilled, and advantageously planarized with the mask material retained over the gate material. Any dielectric material may be deposited at block 166, including SiO, SiN, SiON, or low-k dielectric material, etc. Methods 101 then end at output 170 where the transistor structures and/or transistor interconnects are completed, for example according to any known techniques.

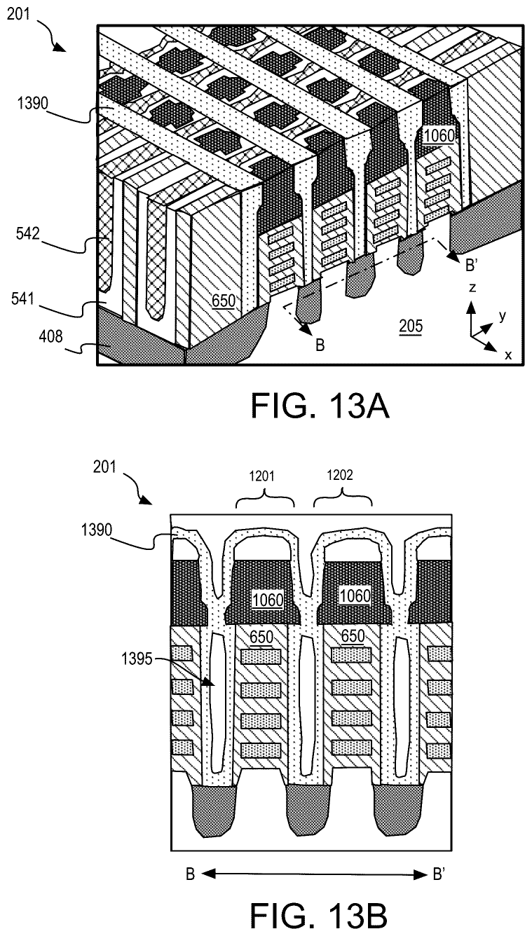

In the example illustrated in FIG. 13A, dielectric material 1390 has been deposited over workpiece portion 201 and then planarized with surrounding mask material 1060 and spacer materials 541, 542. Notably, the necked or shouldered profile of each cap of mask material 1060 within the y-z plane may be advantageously levered for air-gap isolation between gate material of adjacent transistor structures. In FIG. 13B, for example, gate material 650 of transistor structure 1201 is separated from gate material 650 of transistor structure 1202 by an air gap, space, or void 1395 where there is no dielectric material 1390. Such a structure may offer lower effective transistor capacitance than for structures where dielectric material 1390 completely fills the trench between two adjacent transistor structures. To form voids 1395, dielectric material 1390 may occlude the voids 1395 at a pinch point between adjacent caps of mask material 1060. Occlusion may be achieved with a substantially conformal deposition process, for example.

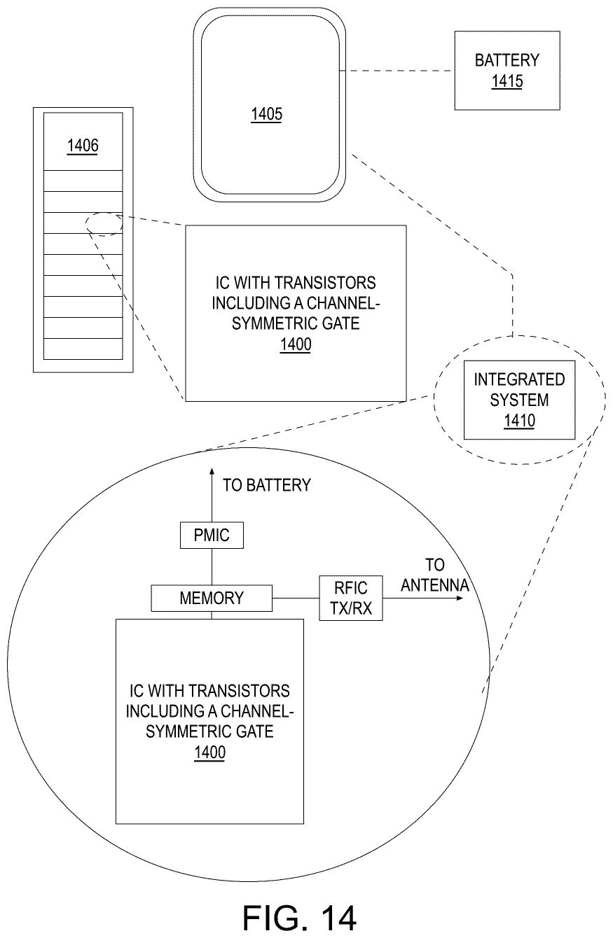

The transistor structures described above may be employed in a wide range of IC devices and further integrated in a wide range of computer-based applications. FIG. 14 illustrates a mobile computing platform 1405 and a server machine 1406 employing a packaged IC die including a channel-symmetric gate, for example as described elsewhere herein. Server machine 1406 may be any commercial server, for example including any number of high-performance computing platforms disposed within a rack and networked together for electronic data processing, which in the exemplary embodiment includes a packaged IC die comprising a fin-symmetrical gate, for example as described elsewhere herein.

The mobile computing platform 1405 may be any portable device configured for each of electronic data display, electronic data processing, wireless electronic data transmission, or the like. For example, the mobile computing platform 1405 may be any of a tablet, a smart phone, laptop computer, etc., and may include a display screen (e.g., a capacitive, inductive, resistive, or optical touchscreen), an integrated system 1410, and a battery 1415.

As illustrated in the expanded view, one or more of a power management integrated circuit (PMIC) or RF (wireless) integrated circuit (RFIC) including a wideband RF (wireless) transmitter and/or receiver may be further coupled to IC 1400. A PMIC may perform battery power regulation, DC-to-DC conversion, etc., and so has an input coupled to battery 1415 and an output providing a current supply to other functional modules. An RFIC may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G and beyond.

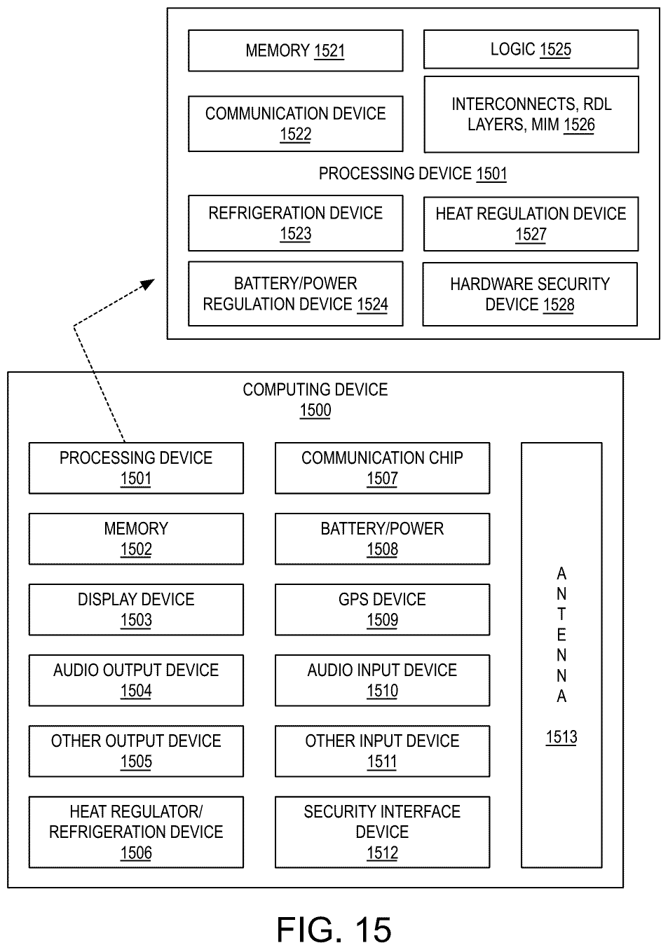

FIG. 15 is a block diagram of a cryogenically cooled computing device 1500 in accordance with some embodiments. For example, one or more components of computing device 1500 may include any of the channel-symmetric gate structures discussed elsewhere herein. A number of components are illustrated in FIG. 15 as included in computing device 1500, but any one or more of these components may be omitted or duplicated, as suitable for the application. In some embodiments, some or all of the components included in computing device 1500 may be attached to one or more printed circuit boards (e.g., a motherboard). In some embodiments, various ones of these components may be fabricated onto a single system-on-a-chip (SoC) die. Additionally, in various embodiments, computing device 1500 may not include one or more of the components illustrated in FIG. 15, but computing device 1500 may include interface circuitry for coupling to the one or more components. For example, computing device 1500 may not include a display device 1503, but may include display device interface circuitry (e.g., a connector and driver circuitry) to which display device 1503 may be coupled.

Computing device 1500 may include a processing device 1501 (e.g., one or more processing devices). As used herein, the term processing device or processor indicates a device that processes electronic data from registers and/or memory to transform that electronic data into other electronic data that may be stored in registers and/or memory. Processing device 1501 may include a memory 1521, a communication device 1522, a refrigeration/active cooling device 1523, a battery/power regulation device 1524, logic 1525, interconnects 1526 (i.e., optionally including redistribution layers (RDL) or metal-insulator-metal (MIM) devices), a heat regulation device 1527, and a hardware security device 1528.

Processing device 1501 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1501 may include a memory 1502, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1521 includes memory that shares a die with processing device 1501. This memory may be used as cache memory and may include embedded dynamic random-access memory (eDRAM) or spin transfer torque magnetic random-access memory (STT-M RAM).

Computing device 1500 may include a heat regulation/refrigeration device 1506. Heat regulation/refrigeration device 1506 may maintain processing device 1501 (and/or other components of computing device 1500) at a predetermined low temperature during operation. This predetermined low temperature may be any temperature discussed elsewhere herein.

In some embodiments, computing device 1500 may include a communication chip 1507 (e.g., one or more communication chips). For example, the communication chip 1507 may be configured for managing wireless communications for the transfer of data to and from computing device 1500. The term “wireless” and its derivatives may be used to describe circuits, devices, systems, methods, techniques, communications channels, etc., that may communicate data through the use of modulated electromagnetic radiation through a nonsolid medium.

Communication chip 1507 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1507 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1507 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1507 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1507 may operate in accordance with other wireless protocols in other embodiments. Computing device 1500 may include an antenna 1513 to facilitate wireless communications and/or to receive other wireless communications (such as AM or FM radio transmissions).

In some embodiments, communication chip 1507 may manage wired communications, such as electrical, optical, or any other suitable communication protocols (e.g., the Ethernet). As noted above, communication chip 1507 may include multiple communication chips. For instance, a first communication chip 1507 may be dedicated to shorter-range wireless communications such as Wi-Fi or Bluetooth, and a second communication chip 1507 may be dedicated to longer-range wireless communications such as GPS, EDGE, GPRS, CDMA, WiMAX, LTE, EV-DO, or others. In some embodiments, a first communication chip 1507 may be dedicated to wireless communications, and a second communication chip 1507 may be dedicated to wired communications.

Computing device 1500 may include battery/power circuitry 1508. Battery/power circuitry 1508 may include one or more energy storage devices (e.g., batteries or capacitors) and/or circuitry for coupling components of computing device 1500 to an energy source separate from computing device 1500 (e.g., AC line power).

Computing device 1500 may include a display device 1503 (or corresponding interface circuitry, as discussed above). Display device 1503 may include any visual indicators, such as a heads-up display, a computer monitor, a projector, a touchscreen display, a liquid crystal display (LCD), a light-emitting diode display, or a flat panel display, for example.

Computing device 1500 may include an audio output device 1504 (or corresponding interface circuitry, as discussed above). Audio output device 1504 may include any device that generates an audible indicator, such as speakers, headsets, or earbuds, for example.

Computing device 1500 may include an audio input device 1510 (or corresponding interface circuitry, as discussed above). Audio input device 1510 may include any device that generates a signal representative of a sound, such as microphones, microphone arrays, or digital instruments (e.g., instruments having a musical instrument digital interface (MIDI) output).

Computing device 1500 may include a global positioning system (GPS) device 1509 (or corresponding interface circuitry, as discussed above). GPS device 1509 may be in communication with a satellite-based system and may receive a location of computing device 1500, as known in the art.

Computing device 1500 may include another output device 1505 (or corresponding interface circuitry, as discussed above). Examples include an audio codec, a video codec, a printer, a wired or wireless transmitter for providing information to other devices, or an additional storage device.

Computing device 1500 may include another input device 1511 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1500 may include a security interface device 1512. Security interface device 1512 may include any device that provides security measures for computing device 1500 such as intrusion detection, biometric validation, security encode or decode, managing access lists, malware detection, or spyware detection. In some examples, security interface device 1512 comprises OTP ROM further including a via MIM fuse, for example as described elsewhere herein.

Computing device 1500, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments so described, but instead can be practiced with modification and alteration without departing from the scope of the appended claims. For example, the above embodiments may include specific combinations of features as further provided below.

In first examples, an integrated circuit (IC) structure comprises a transistor over a plane of the IC structure. The transistor comprises a channel material of a first lateral width, and a first portion of gate material adjacent to a sidewall of the channel material, the first portion of gate material extending a first height from the plane. The iC structure comprises a gate mask material over a second portion of the gate material directly above the channel material. The gate mask material has a second lateral width, larger than the first lateral width. The second portion of the gate material extends a second height that is within 10 nm of the first height.

In second examples, for any of the first examples the second height is within 5 nm of the first height.

In third examples, for any of the first through second examples the second height is no greater than the first height.

In fourth examples, for any of the first through third examples a lateral width of the second portion of the gate material summed with twice the lateral width of the first portion of the gate material is smaller than the second lateral width, but larger than the first lateral width.

In fifth examples, for any of the first through fourth examples the IC structure comprises an insulator material or an air gap bifurcating the first portion of the gate material from a third portion of the gate material that extends a third height, wherein the third height is more than 10 nm greater than the first height and the second height

In sixth examples, for any of the fifth examples a top surface of the third portion of the gate material is substantially coplanar with a top surface of a spacer dielectric material separating the first portion of the gate material from a source material or a drain material.

In seventh examples, for any of the sixth examples the IC structure further comprises an electrical routing feature comprising the third portion of the gate material.

In eighth examples, for any of the first examples, a centerline of the channel material is substantially coincident with a centerline of the gate mask material.

In ninth examples, for any of the first through eighth examples the transistor structure comprises a source material and a drain material coupled at opposite ends of the channel material within a dimension substantially orthogonal to the first width. The source material and the drain material each comprises an impurity and is epitaxial to the channel material. The source material and the drain material each has a lateral width larger than the first lateral width, and that is asymmetrical about a centerline of the first lateral width.

In tenth examples, for any of the first through ninth examples the channel material comprises a first channel material layer in a stack with a second channel material layer.

In eleventh examples, an integrated circuit (IC) device comprises a first transistor structure comprising a first channel material having a first lateral width in a first dimension. The first transistor comprises a first portion gate material over, and adjacent to the channel material. The first portion of gate material extends a first height in a second dimension orthogonal to a reference plane. The IC device comprises a first gate mask structure over the first portion of the gate material. The first gate mask structure and has a second lateral width in the first dimension, the second lateral width larger than the first lateral width. The IC device comprises a second transistor structure laterally adjacent to a first side of the first transistor structure. The second transistor structure comprises a second channel material having the first lateral width in the first dimension, and a second portion of the gate material over, and laterally adjacent to, the second channel material. The second portion of the gate material extends the first height in the second dimension. The IC device comprises a second gate mask structure over the second portion of the gate material. The second gate mask structure and has the second lateral width. A third portion of the gate material is laterally adjacent to a second side of the first transistor structure, opposite the second transistor structure. The third portion of the gate material extends a second height in the second dimension. The second height is greater than the first height by more than 10 nm.

In twelfth examples, for any of the eleventh examples a top surface of the third portion of the gate material is substantially coplanar with a top surface of at least the first gate mask structures.

In thirteenth examples, for any of the eleventh through twelfth examples the IC structure further comprises an electrical routing feature comprising the third portion of the gate material.

In fourteenth examples, for any of the eleventh through thirteenth examples the IC device comprises an insulator material or an air gap bifurcating the first portion of the gate material from the second portion of the gate material.

In fifteenth examples, for any of the fourteenth examples the insulator material or a second air gap bifurcates the third portion of the gate material from the first portion of the gate material.

In sixteenth examples a method comprises patterning a first mask material over a transistor channel material, the first mask material of a first width in a first dimension. The method comprises forming a gate material adjacent to a sidewall of the transistor channel material and adjacent to a sidewall of the first mask material. The method comprises selectively forming a second mask material over the gate material, and adjacent to the first mask material. The method comprises exposing a sidewall of the gate material by thinning the first mask material. The method comprises recessing the sidewall of the gate material to define an opening of a second width in the first dimension, larger than the first width. The method comprises depositing a third mask material into the opening, and removing a portion of the gate material unprotected by the third mask material.

In seventeenth examples, for any of the sixteenth examples the first mask material comprises at least a top material layer over a bottom material layer, the bottom material layer proximal to the transistor channel material. Thinning the first mask material comprises removing the top material while retaining the bottom material layer, and the bottom material layer protects an underlying portion of the gate material while recessing the sidewall of the gate material.

In eighteenth examples, for any of the sixteenth through seventeenth examples selectively forming the second mask material comprises selectively depositing amorphous silicon directly on a surface of the gate material.

In nineteenth examples, for any of the sixteenth through eighteenth examples patterning the first mask material defines first lines extending in a second direction, orthogonal to the first dimension, and removing the portion of the gate material comprises etching a trench through a portion of the gate material between the third mask material and a planar substrate surface below the transistor channel material.

In twentieth examples, for any of the nineteenth examples the method comprises defining etch mask lines over the third mask material, the etch mask lines substantially parallel to the first lines, and etching the trench within a space between adjacent ones of the etch mask lines.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should, therefore, be determined with reference to the appended claims, along with the full scope of equivalents to which such claims are entitled.

What is claimed is:

1. An integrated circuit (IC) structure, comprising:
a transistor over a plane of the IC structure, the transistor comprising:
a channel material of a first lateral width; and
a first portion of gate material adjacent to a sidewall of the channel material, the first portion of gate material extending a first height from the plane; and
a gate mask material over a second portion of the gate material directly above the channel material, the gate mask material having a second lateral width, larger than the first lateral width, wherein the second portion of the gate material extends a second height that is within 10 nm of the first height.

2. The IC structure of claim 1, wherein the second height is within 5 nm of the first height.

3. The IC structure of claim 2, wherein the second height is no greater than the first height.

4. The IC structure of claim 1, wherein a lateral width of the second portion of the gate material summed with twice the lateral width of the first portion of the gate material is smaller than the second lateral width, but larger than the first lateral width.

5. The IC structure of claim 1, further comprising an insulator material or an air gap bifurcating the first portion of the gate material from a third portion of the gate material that extends a third height, wherein the third height is more than 10 nm greater than the first height and the second height

6. The IC structure of claim 1, wherein a top surface of the third portion of the gate material is substantially coplanar with a top surface of a spacer dielectric material separating the first portion of the gate material from a source material or a drain material.

7. The IC structure of claim 6, wherein the IC structure further comprises an electrical routing feature comprising the third portion of the gate material.

8. The IC structure of claim 1, wherein a centerline of the channel material is substantially coincident with a centerline of the gate mask material.

9. The IC structure of claim 1, further comprising:
a source material and a drain material coupled at opposite ends of the channel material within a dimension substantially orthogonal to the first width, wherein:
the source material and the drain material each comprises an impurity and is epitaxial to the channel material; and
the source material and the drain material each has a lateral width larger than the first lateral width, and that is asymmetrical about a centerline of the first lateral width.

10. The IC structure of claim 1, wherein the channel material comprises:
a first channel material layer in a stack with a second channel material layer.

11. An integrated circuit (IC) device, comprising:
a first transistor structure comprising:
a first channel material having a first lateral width in a first dimension; and
a first portion gate material over, and adjacent to the channel material, wherein the first portion of gate material extends a first height in a second dimension orthogonal to a reference plane;
a first gate mask structure over the first portion of the gate material, wherein the first gate mask structure and has a second lateral width in the first dimension, the second lateral width larger than the first lateral width;
a second transistor structure laterally adjacent to a first side of the first transistor structure, the second transistor structure comprising:
a second channel material having the first lateral width in the first dimension; and
a second portion of the gate material over, and laterally adjacent to, the second channel material, wherein the second portion of the gate material extends the first height in the second dimension;
a second gate mask structure over the second portion of the gate material, wherein the second gate mask structure and has the second lateral width; and
a third portion of the gate material laterally adjacent to a second side of the first transistor structure, opposite the second transistor structure, the third portion of the gate material extending a second height in the second dimension, the second height greater than the first height by more than 10 nm.

12. The IC device of claim 11, wherein a top surface of the third portion of the gate material is substantially coplanar with a top surface of at least the first gate mask structures.

13. The IC structure of claim 11, wherein the IC structure further comprises an electrical routing feature comprising the third portion of the gate material.

14. The IC device of claim 11, further comprising an insulator material or an air gap bifurcating the first portion of the gate material from the second portion of the gate material.

15. The IC device of claim 14, further comprising the insulator material or a second air gap bifurcating the third portion of the gate material from the first portion of the gate material.

16. A method, comprising:
patterning a first mask material over a transistor channel material, the first mask material of a first width in a first dimension;
forming a gate material adjacent to a sidewall of the transistor channel material and adjacent to a sidewall of the first mask material;
selectively forming a second mask material over the gate material, and adjacent to the first mask material;
exposing a sidewall of the gate material by thinning the first mask material;
recessing the sidewall of the gate material to define an opening of a second width in the first dimension, larger than the first width;
depositing a third mask material into the opening; and
removing a portion of the gate material unprotected by the third mask material.

17. The method of claim 16, wherein:
the first mask material comprises at least a top material layer over a bottom material layer, the bottom material layer proximal to the transistor channel material;
thinning the first mask material comprises removing the top material while retaining the bottom material layer; and
the bottom material layer protects an underlying portion of the gate material while recessing the sidewall of the gate material.

18. The method of claim 16, wherein selectively forming the second mask material comprises selectively depositing amorphous silicon directly on a surface of the gate material.

19. The method of claim 16, wherein:
patterning the first mask material defines first lines extending in a second direction, orthogonal to the first dimension; and
removing the portion of the gate material comprises etching a trench through a portion of the gate material between the third mask material and a planar substrate surface below the transistor channel material.

20. The method of claim 19, further comprising defining etch mask lines over the third mask material, the etch mask lines substantially parallel to the first lines, and etching the trench within a space between adjacent ones of the etch mask lines.
